(19) United States
(12) Patent Application Publication
(10) Pub. No.: US 2006/0181307 A1
(43) Pub. Date: Aug. 17, 2006

(54) Semiconductor integrated circuit and method for laying-out and wiring the semiconductor integrated circuit

(76) Inventors: Kenichi Shibayashi, Tokyo (JP); Hidekazu Kikuchi, Tokyo (JP)

Correspondence Address: RABIN & Berdo, PC, 1101 14TH STREET, NW, SUITE 500, WASHINGTON, DC, 20005, US

(21) Appl. No.: 11/345,372

(22) Filed: Feb. 2, 2006

(30) Foreign Application Priority Data
Feb. 14, 2005 (JP) 2005-036168

(51) Int. Cl. H03K 19/177

(52) U.S. Cl. 326/41

(57) ABSTRACT

A semiconductor integrated circuit includes a plurality of rows of wired standard cells formed on a semiconductor substrate. The wires standard cells are wired to provide a desired function. Spare standard cells are also formed in each of the plurality of rows in an area in which the wired standard cells are not formed, but are not wired in an initial design. When a change of the function is required, the spare standard cells are wired to achieve a desired additional function. Two power supply lines extend in a direction in which the wired standard cells and spare standard cells are aligned. The wired standard cells and spare standard cells are located between the first power supply line and the second power supply line. Each of the spare standard cells includes a plurality of electrically isolated transistors that may be combined to implement a logic function.

### BACKGROUND OF THE INVENTION

1. Field of the Invention

The present invention relates to a semiconductor integrated circuit configured with standard cells, and to a method for laying out the standard cells and wiring the standard cells into a semiconductor integrated circuit of a specific design. More particularly, the present invention relates to an integrated circuit and a method in which functions of the integrated circuit can be easily altered.

2. Description of the Related Art

Among conventional design methods for designing an integrated circuit is a standard cell design in which a plurality of standard cells having a certain logic function are formed on a semiconductor substrate and the standard cells are wired together to meet the user's needs, thereby implementing desired functions.

With the standard cell design, the design of the standard cells may have to be changed if the functions of an integrated circuit are to be altered after the standard cells have been laid out on a semiconductor substrate. This may necessitate redesign of all the manufacturing masks for the integrated circuit. The redesign of manufacturing masks causes a serious increase in manufacturing cost of the semiconductor integrated circuit.

Japanese Patent Laid-Open No. 10-242289 discloses one way of solving the aforementioned problem. A gate array aligned in a grid pattern is formed in a region where standard cells are not formed. The cells of the gate array are selectively wired together using a wiring layer, thereby changing the function of the integrated circuit. This configuration allows alteration of functions by merely changing the wiring layer, thereby shortening a period required for design change.

For such a configuration disclosed in Japanese Patent Laid-Open No. 10-242289, desired logic functions are implemented by wiring the basic cells having a predetermined transistor configuration. This configuration places some limitations on the lay-out of the integrated circuit. As a result, a logic circuit to be added tends to occupy a relatively large area. If the size of available area is small, then necessary number of basic cells cannot be laid out, thus causing difficulties in addressing design change.

In wiring the basic cells together to implement a desired function, the wires may cause some signal delay with the result that the manufacturing processes for configuring additional logic circuits may be complex.

### SUMMARY OF THE INVENTION

An object of the invention is to provide a semiconductor integrated circuit in which additional logic circuits may be formed in a limited unwired area on a semiconductor substrate or a large design change may be made using the limited unwired area without the need for complex processes.

A semiconductor integrated circuit is configured such that a plurality of first standard cells are arranged on a semiconductor substrate and are selectively wired to provide a function. The plurality of rows of the first standard cells are formed on the substrate. At least one second standard cell is formed in each of the plurality of rows and is used when a change of function is required. The at least one second standard cell is formed in an area in which the first standard cells are not formed.

The second standard cell is one of a plurality of second standard cells.

Each of the plurality of rows includes two power supply lines that extend in a direction in which the first standard cells are aligned.

Each of the second standard cells includes a plurality of electrically isolated transistors.

Each of the second standard cells includes a plurality of logic gates combined to implement a logic function.

A semiconductor integrated circuit is configured such that a plurality of first standard cells are arranged on a semiconductor substrate and are selectively wired to provide a function. A plurality of rows of the first standard cells are formed on the substrate. A plurality of second standard cells are formed in each of the plurality of rows, and are used when the function is modified. The plurality of second standard cells are formed in areas in which the first standard cells are not formed.

A semiconductor integrated circuit is configured such that a plurality of first standard cells are arranged on a semiconductor substrate and are selectively wired to provide a function. A plurality of rows of the first standard cells is formed on the substrate. At least one second standard cell is formed in each of the plurality of rows, being formed in an area in which the first standard cells are not formed. The at least one second standard cell is used when the function is modified. A first power supply line and a second power supply line extend in parallel to each of the plurality of rows such that the first standard cells and the at least one second standard cell are between the first power supply line and the second power supply line.

A semiconductor integrated circuit is configured such that a plurality of first standard cells are arranged on a semiconductor substrate and are selectively wired to provide a function. A plurality of rows of the first standard cells is formed on the substrate. A first power supply line and a second power supply line extend in parallel to each of the plurality of rows such that the first standard cells are between the first power supply line and the second power supply line. A fraction of the first standard cells is electrically connected to the first power supply line and the second power supply line and a remaining fraction of the first standard cells not being connected to the first power supply line and the second power supply line.

A method of wiring a semiconductor integrated circuit is configured such that a plurality of first standard cells are formed on a semiconductor substrate and wired to one another to implement an integrated circuit that performs a function. The method includes steps of:

forming a plurality of rows on a semiconductor substrate, each of the plurality of rows including a plurality of first standard cells and at least one second standard cell aligned in a line; and

wiring the at least one second standard cell to implement a logic circuit when a change of the function is required, the logic circuit being wired to the integrated circuit.

The wiring includes electrically connecting elements in the at least one second standard cell to one another, and connecting the at least one second standard cell to the first standard cells.

The elements of the at least one second standard cell is a plurality of logic gates and a combination of the plurality of logic gates performs a logic function.

A fraction of the plurality of logic gates are selectively wired to one another.

The at least one second standard cell is in one of the plurality of rows that is closest to a standard cell to which the at least one second standard cell is electrically connected.

A method of wiring a semiconductor integrated circuit is configured such that a plurality of first standard cells are formed on a semiconductor substrate and wired to one another to implement an integrated circuit that performs a function. The method includes:

providing a semiconductor substrate; and

forming a plurality of rows on a semiconductor substrate, each of the plurality of rows including the first plurality of standard cells and at least one second standard cell aligned in a line.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limiting the present invention, and wherein:

FIG. 1 is a front view of a semiconductor integrated circuit according to the present invention;

FIG. 2 is an enlarged view of an example of a row of cells;

FIG. 3 is an enlarged view of spare standard cells having a logic function, for example, a flip flop;

FIG. 4 illustrates a specific logic function (i.e., flip flop) formed of the spare standard cells in FIG. 3;

FIG. 5 is a front view of a modified semiconductor integrated circuit;

FIG. 6 is a front view of another modified semiconductor integrated circuit;

FIGS. 7 and 8 illustrate the outline of the modification for changing functions;

FIG. 9 illustrates a flip-flop circuit; and

FIG. 10 illustrates the lay-out of the spare standard cells that configure the flip-flop circuit.

### DETAILED DESCRIPTION OF THE INVENTION

An embodiment and modifications of the invention will be described in detail with reference to the accompanying drawings. Like elements have been given like reference numerals throughout the specification.

### EMBODIMENT

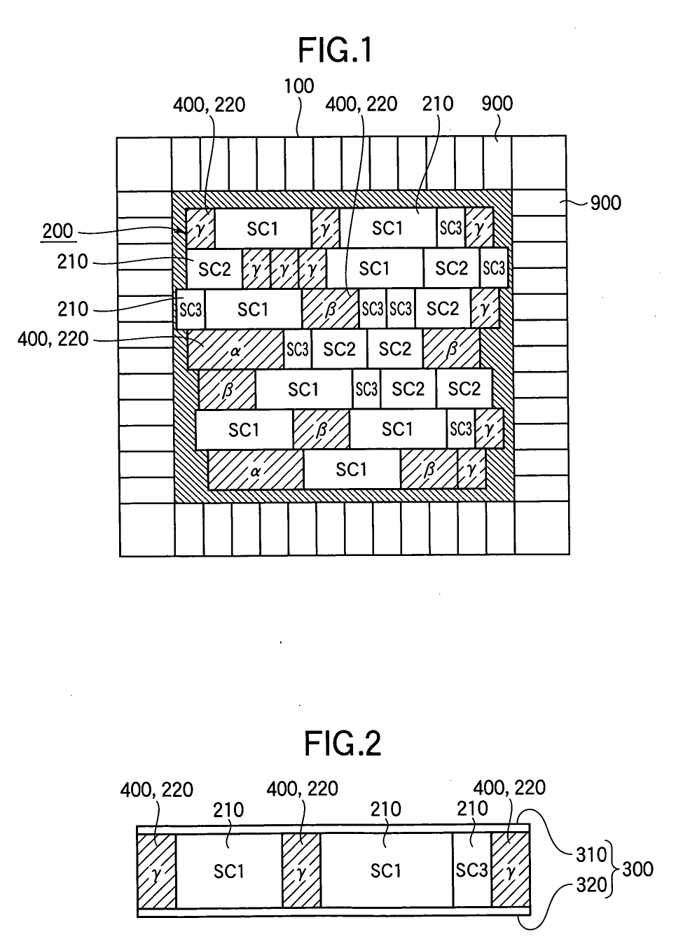

FIG. 1 is a schematic view of a semiconductor integrated circuit according to the present invention. Referring to FIG. 1, a plurality of standard cells 210 (SC1-SC3) are arranged on a semiconductor substrate 100.

The semiconductor substrate 100 is a silicon (Si) substrate. A plurality of peripheral cells 900 are arranged on a peripheral portion of the semiconductor substrate 100. The peripheral cells 900 are used for receiving signals from external circuits and outputting signals to the external circuits. The peripheral cells 900 include circuits that perform various functions and pads through which the semiconductor integrated circuit is electrically connected to the external circuits by means of bonding wires.

Standard cells 210 (i.e., SC1-SC3) are aligned in a line, and perform logical functions of a specific design. The standard cells 210 include a plurality of transistors formed on the semiconductor substrate 100 and wires that electrically interconnect the respective transistors.

The following description assumes that the transistors in each of the standard cells 210 include an impurity diffusion layer and gate electrodes formed on the semiconductor substrate 100. The transistors in the standard cell 210 share a common impurity diffusion layer so that the transistors occupy a minimum area. Reference numerals SC1, SC2, and SC3 are, for example, a flip-flop circuit, an AND gate, and a NAND gate, respectively, and thus have different logic functions from one another. These standard cells 210 may be interconnected by wires to form an integrated circuit as a whole on the semiconductor substrate 100, the integrated circuit performing a desired specific function. A plurality of rows 200 of standard cells are formed on the semiconductor substrate 100.

FIG. 2 is an enlarged view of an example of a row 200 of cells. A plurality of rows 200 of cells are formed on the semiconductor substrate 100. Each row 200 includes standard cells 210 aligned in a direction in which the row 200 extends. Referring to FIG. 2, a power supply line 300 includes a high-potential wire (VDD) 310 and a low-potential wire (GND) 320, which extend parallel to each other along the line of the standard cells 210 in the row 200. Each of the standard cells 210 is electrically connected to the high-potential wire (VDD) 310 and low-potential wire (GND) 320.

Each row 200 includes areas 400 in which the standard cells 210 are not formed. The areas 400 are provided for accommodating wires that interconnect among the respective standard cells 210.

In addition to the standard cells 210, spare standard cells 220 (i.e., α, β, and γ) are formed in the area 400. When the functions of the integrated circuit are modified, the spare standard cells 220 (i.e., α, β, and γ) are used. In other words, the standard cells 210 and spare standard cells 220 are aligned in the same line.

The spare standard cells 220 are formed of a plurality of transistors, and perform their designed logical functions. These transistors may share a common impurity diffusion layer so that the transistors occupy a minimum area. It is to be noted that the spare standard cells 220 have not been wired to one another yet. In the present embodiment, at least one of the spare standard cells 220 performs a logic function such as a flip-flop circuit, which is implemented by combining a plurality of logic gates.

The spare standard cells α, β, and γ are, for example, a flip-flop circuit, a NAND gate, an AND gate, respectively.

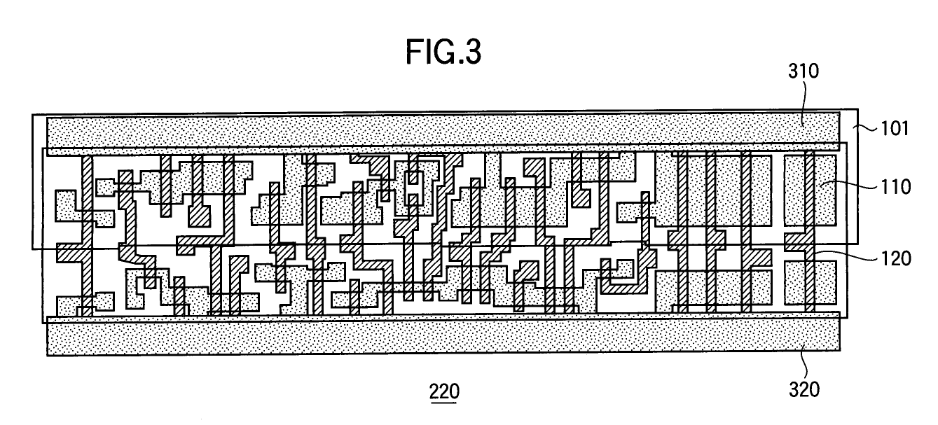

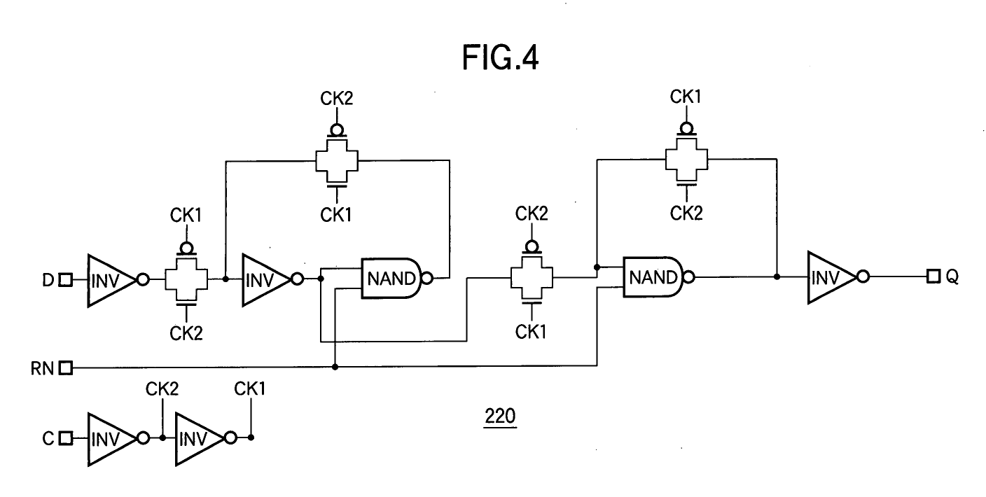

FIG. 3 is an enlarged view of the spare standard cells 220 having a logic function, for example, a flip-flop in FIG. 4. FIG. 4 illustrates a specific logic function (i.e., flip-flop) formed of the spare standard cells 220 in FIG. 3.

Referring to FIG. 4, the flip-flop circuit has a data input terminal D, reset signal input terminal RN, clock signal input terminal C, and data output terminal Q.

Referring to FIG. 3, the spare standard cells 220 are designed so as to perform predetermined logic functions, and are formed of a plurality of transistors that are constructed of impurity diffusion layers 110 and gate electrodes 120 of poly-silicon, which are formed on the semiconductor substrate 100.

The high-potential wire (VDD) 310 and low-potential wire (GND) 320 extend in parallel with each other with the transistors lying between the high-potential wire 310 and low-potential wire 320. A well 101 is formed on the semiconductor substrate 100.

The spare standard cells 220 are not used at an initial circuit design and are merely in the form of, for example, an array in which a plurality of transistors are electrically isolated from one another. For example, as shown in FIG. 3, a plurality of transistors share a common impurity diffusion layer 110, thereby occupying a minimum area on the semiconductor substrate 100. In other words, a plurality of gate electrodes 120 are formed on the common impurity diffusion layer 110.

{Modification to the Functions of the Integrated Circuit}

A modification to the semiconductor integrated circuit according to the present embodiment will be described. The transistors in the spare standard cells 220 are wired to one another to form additional logic circuits that are required for modifying the semiconductor integrated circuit. Then, the standard cells 210 and wired spare standard cells 220 are then electrically connected to make an integrated circuit that has modified functions on the semiconductor substrate 100.

If each row 200 includes a plurality of spare standard cells 220 that have a desired function, a desired spare standard cell 220 is selected from among the plurality of spare standard cells 220 so that the wires for connecting between the desired standard cell 220 and the standard cell 210 are shortest.

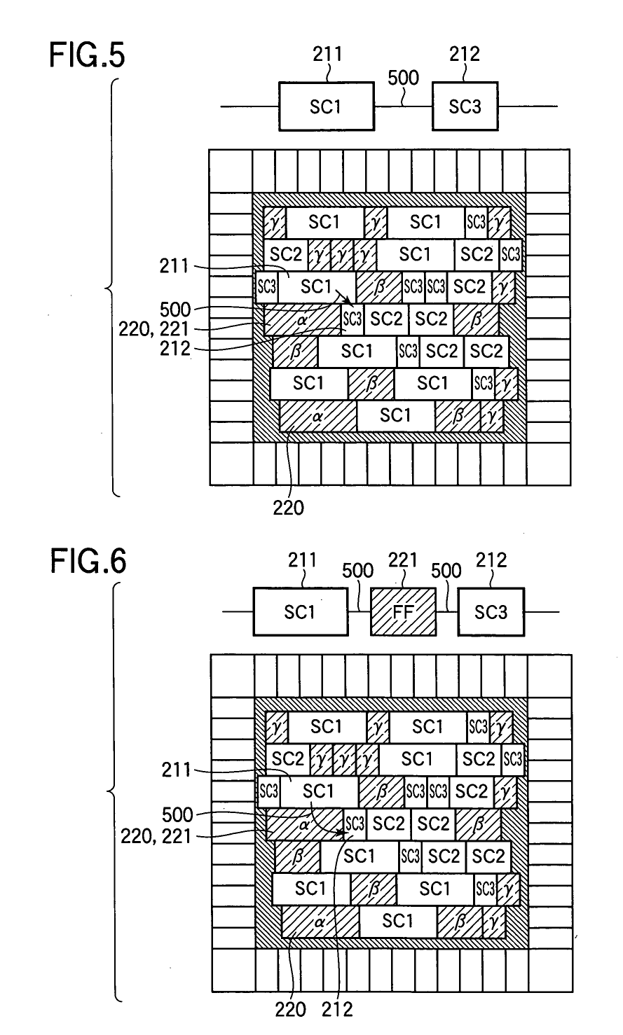

FIG. 5 is a front view of a modified semiconductor integrated circuit. An example will be described where a flip-flop circuit 221 is inserted between the standard cell 211 (SC1) and the standard cell 212 (SC3) in FIG. 5.

Referring to FIG. 5, the standard cell 211 and standard cell 212 are electrically connected via a wire 500 in an initial design. If a flip-flop circuit 221 (FIG. 6) is to be inserted between the standard cells 211 and 212, components in the spare standard cell 220 (α) that has been laid out in a flip-flop configuration are wired to form the flip-flop circuit 221.

A spare standard cell 221, which is closest to the standard cell 211 and standard cell 212, is selected from among the plurality of spare standard cells 220 (α). Referring to FIG. 6, the standard cell 221 which have now been wired into the flip-flop circuit 221 is electrically connected to the standard cell 211 and the standard cell 212 by means of wires 500. This completes the modification.

{Another Modification to the Functions of the Integrated Circuit}

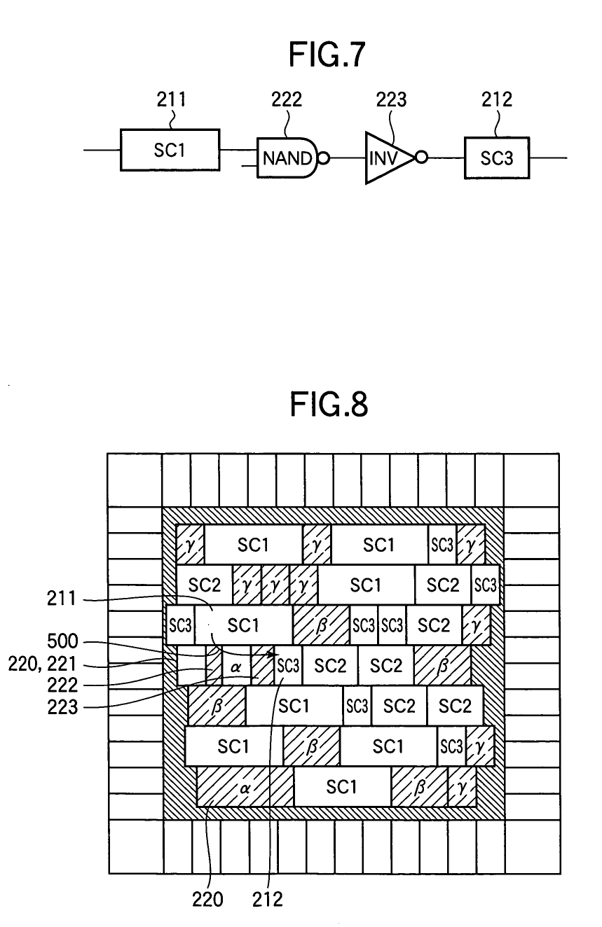

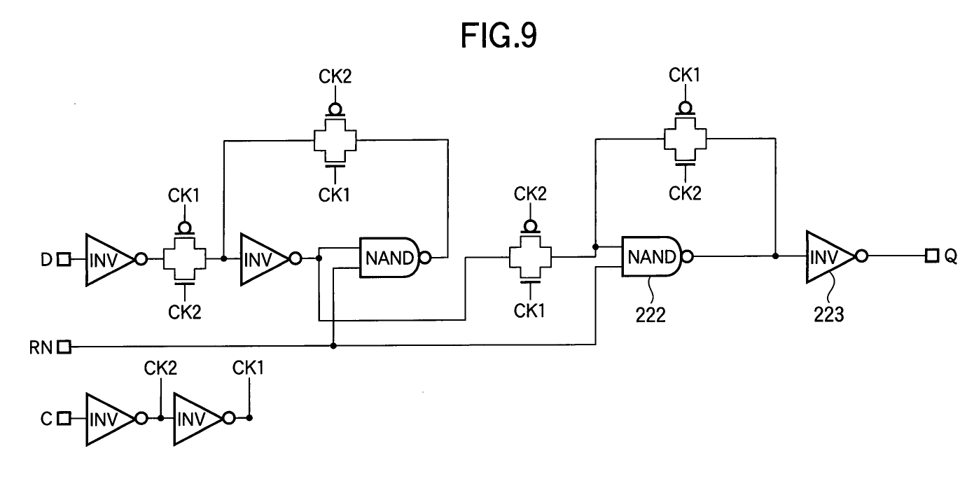

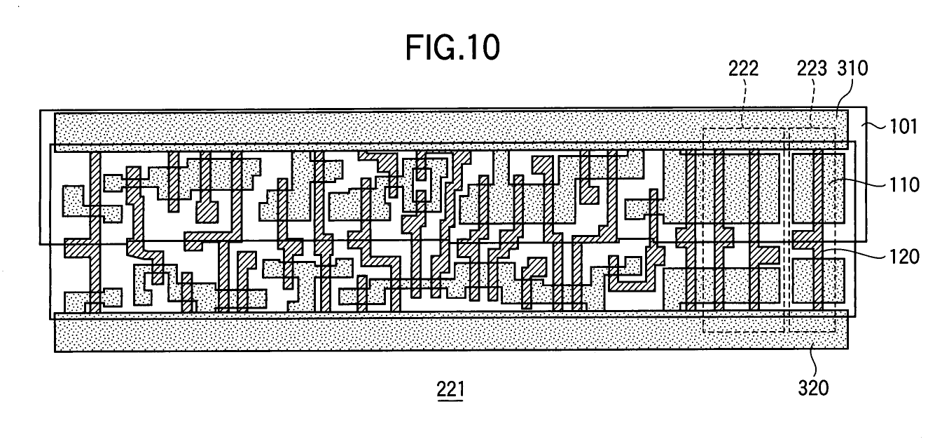

Another example of modification assumes that a NAND gate 222 and an inverter 223 are inserted between the standard cell 211 (SC1) and the standard cell 212 (SC3). The example of modification will be described with reference to FIGS. 7-10. FIGS. 7 and 8 illustrate the outline of the modification for changing functions. FIG. 9 illustrates a flip-flop circuit for illustrating the change of the function of the semiconductor integrated circuit. FIG. 10 illustrates the lay-out of the spare standard cell 221 with which the flip-flop circuit in FIG. 9 is configured.

Referring to FIG. 10, the components or transistors of the standard cell 221 (α) are arranged such that the components could be wired to form a flip-flop circuit. Here, in order to insert the NAND gate 222 and inverter 223 between the standard cell 211 (SC1) and the standard cell 212 (SC3) of an initial design, some of the components (i.e., transistors) of the standard cell 221 (α) are selectively wired to form the NAND gate 222 and the inverter 223.

An area surrounded by dotted lines 222 in FIG. 10 corresponds to the NAND gate 222 of the flip-flop circuit in FIG. 9. An area surrounded by dotted lines 223 in FIG. 10 corresponds to the inverter 223 of the flip-flop in FIG. 9.

A desired standard cell 220 (α) closest to both the standard cell 211 and the standard cell 212 is selected from among the plurality of spare standard cells 220, so that the wires connecting between the desired standard cell 220 (α) and the standard cell 211, and between the desired standard cell 220 (α) and the standard cell 212 are shortest.

Referring to FIG. 8, the functions of the semiconductor integrated circuit are altered by electrically connecting the NAND gate 222 and the inverter 223 between the standard cell 211 and the standard cell 212.

As described above, unwired spare standard cells 220 are formed in the areas 400 in an initial design, so that when the function of the integrated circuit is to be changed, it is only necessary to change the wiring layer to electrically connect the unwired spare standard cells into an additional circuit. This shortens the time required for developing a modified integrated circuit.

In the present invention, the spare standard cells 220 are provided for a situation where the function of an integrated circuit should be changed. Thus, when the function of a semiconductor integrated circuit should be altered, the addition of logic circuits can be accomplished by using a limited small area and the wiring required for adding the logic circuits can be performed easily.

The configuration of the invention allows alteration of the integrated circuit even if the size of an available area for a circuit to be added is relatively small or the modification requires a large-scale logic circuit.

Because the spare standard cells 220 are formed in a row 200 of cell, when the function of an integrated circuit is to be altered, the power supply line 300 formed in the row 200 of cell can be used. In other words, the spare standard cells 220 can share the power supply line 300 with the standard cells 210. This eliminates the need for providing exclusive, additional power supply lines for driving the spare standard cells 220.

The wires that connect the spare standard cells 220 to the standard cells 210 can be routed in a shorter distance when the spare standard cells 220 are formed in the areas 400 of each row of cells than when the spare standard cells 220 are concentrated in one particular area on the semiconductor substrate 100.

Because the spare standard cells 220 are arranged all over the semiconductor substrate 100, an additional circuit can be made by using a spare standard cell(s) 220 in the same row 200 of cell or a spare standard cell(s) 220 in the adjacent row 200 of cell, taking the shortest distance to the standard cell 210 into account.

Thus, the configuration of the present invention can simplify the wiring process (metallization process) for connecting the standard cells 210 to the spare standard cells 220.

The spare standard cell 220 has its own logic function. The spare standard cell 220 includes logic gates configured such that the logic gates may be combined to achieve a specific function. Thus, the spare standard cell can not only be used alone but also can be selectively wired into a single logic circuit or a composite logic circuit.

In modifying the function of a semiconductor integrated circuit, a semiconductor substrate according to the present invention requires only a small area as compared to providing additional individual spare standard cells of a plurality of types on the substrate. Thus, if a semiconductor substrate has a sufficiently large number of areas sufficient for accommodating these spare standard cells, the semiconductor substrate preferably should incorporate the spare standard cells according to the invention instead of forming a plurality of types of spare standard cells of specific design.

The invention being thus described, it will be obvious that the same may be varied in many ways. Such variations are not to be regarded as a departure from the spirit and scope of the invention, and all such modifications as would be obvious to one skilled in the art intended to be included within the scope of the following claims.

What is claimed is:

1. A semiconductor integrated circuit where a plurality of first standard cells are arranged on a semiconductor substrate and are selectively wired to provide a function, the circuit comprising:
a plurality of rows of the first standard cells formed on the substrate; and
at least one second standard cell formed in each of said plurality of rows and used when a change of the function is required, said at least one second standard cell being formed in an area in which the first standard cells are not formed.

2. The semiconductor integrated circuit according to claim 1, wherein said second standard cell is one of a plurality of second standard cells.

3. The semiconductor integrated circuit according to claim 1, wherein each of said plurality of rows includes two power supply lines that extend in a direction substantially parallel to the plurality of rows of said first standard cells are aligned.

4. The semiconductor integrated circuit according to claim 1, wherein each of said second standard cells includes a plurality of electrically isolated transistors.

5. The semiconductor integrated circuit according to claim 1, wherein each of said second standard cells includes a plurality of logic gates combined to implement a logic function.

6. A semiconductor integrated circuit where a plurality of first standard cells are arranged on a semiconductor substrate and are selectively wired to provide a function, the circuit comprising:
a plurality of rows of the first standard cells, said plurality of rows being formed on the substrate; and
a plurality of second standard cells formed in each of said plurality of rows and used when the function is modified, said plurality of second standard cells being formed in areas in which the first standard cells are not formed.

7. A semiconductor integrated circuit where a plurality of first standard cells are arranged on a semiconductor substrate and are selectively wired to provide a function, the circuit comprising:
a plurality of rows of the first standard cells formed on the substrate;
at least one second standard cell formed in each of said plurality of rows, said at least one second standard cell being formed in an area in which the first standard cells are not formed, said at least one second standard cell being used when the function is modified; and
a first power supply line and a second power supply line that extend in parallel to each of said plurality of rows such that the first standard cells and said at least one second standard cell are between said first power supply line and said second power supply line.

8. A semiconductor integrated circuit where a plurality of first standard cells are arranged on a semiconductor substrate and are selectively wired to provide a function, the circuit comprising:
a plurality of rows of the first standard cells formed on the semiconductor substrate; and
a first power supply line and a second power supply line that extend in parallel to each of said plurality of rows such that the first standard cells are between said first power supply line and said second power supply line, a fraction of the first standard cells being electrically connected to said first power supply line and said second power supply line and a remaining fraction of the first standard cells not being connected to said first power supply line and said second power supply line.

9. A method of manufacturing a semiconductor integrated circuit in which a plurality of standard cells are formed on a semiconductor substrate and wired to one another to implement an integrated circuit that performs a function, the method comprising steps of:
forming a plurality of rows each of which includes the plurality of first standard cells and at least one second standard cell aligned in a line; and
wiring the plurality of first standard cells one another to implement the integrated circuit; and
wiring the at least one second standard cell to implement a logic circuit when a change of the function is required, the logic circuit being wired to the integrated circuit.

10. The method according to claim 9, wherein said wiring comprising electrically connecting elements in the at least one second standard cell to one another and connecting the at least one second standard cell to the first standard cells.

11. The method according to claim 9, wherein the elements in the at least one second standard cell are a plurality of logic gates and a combination of the plurality of logic gates performs a logic function.

12. The method according to claim 11, wherein a fraction of the plurality of logic gates are selectively wired to one another.

13. The method according to claim 10, wherein the at least one second standard cell is in one of the plurality of rows, and is closest to a standard cell to which the at least one second standard cell is electrically connected.

14. A method of wiring a semiconductor integrated circuit in which a plurality of first standard cells are formed on a semiconductor substrate and wired to one another to implement an integrated circuit that performs a function, the method comprising:
providing a semiconductor substrate; and
forming a plurality of rows on the semiconductor substrate, each of the plurality of rows including the first plurality of standard cells and at least one second standard cell aligned in a line.
